(19) United States
(12) Patent Application Publication
(10) Pub. No.: US 2024/0332430 A1
(43) Pub. Date: Oct. 3, 2024

(54) SEMICONDUCTOR DEVICE

(71) Applicant: ROHM CO., LTD., Kyoto (JP)

(72) Inventor: Yuji KOGA, Kyoto (JP)

(73) Assignee: ROHM CO., LTD., Kyoto (JP)

(21) Appl. No.: 18/618,797

(22) Filed: Mar. 27, 2024

(30) Foreign Application Priority Data
Mar. 30, 2023 (JP) 2023-056400

(51) Int. Cl. H01L 29/808; H01L 29/08; H01L 29/10

(52) U.S. Cl. CPC H01L 29/808; H01L 29/0847; H01L 29/1058; H01L 29/1066

(57) ABSTRACT

The present disclosure provides a semiconductor device. The semiconductor device includes: a bottom gate region of a first conductivity type and formed in a semiconductor layer; a top gate region of the first conductivity type and formed in a surface layer portion of a first surface of the semiconductor layer, wherein the top gate region faces the bottom gate region along a thickness direction of the semiconductor layer; a source region of a second conductivity type, formed in the surface layer portion of the first surface of the semiconductor layer and separated from the top gate region in a direction along the first surface; and a drain region of the second conductivity type, formed in the surface layer portion of the first surface of the semiconductor layer and separated from the top gate region at an opposite side of the source region in the direction along the first surface.

### TECHNICAL FIELD

The present disclosure relates to a semiconductor device.

### BACKGROUND

Patent document 1 discloses a junction field effect transistor. In a junction field effect transistor, an n-type epitaxial layer is stacked on a semiconductor substrate. A plurality of gate regions are formed at intervals in the n-type epitaxial layer, and source regions are formed between adjacent gate regions at intervals from the gate regions. A gate electrode and a source electrode are connected to the gate region and the source region, respectively. A drain electrode is connected to a back surface of the semiconductor substrate.

### Patent Publication

[Patent document 1] Japan Patent Publication No. 2008-66619

### BRIEF DESCRIPTION OF THE DRAWINGS

FIG. 1 is a schematic perspective view of a semiconductor device according to an embodiment of the present disclosure.

FIG. 2 is a schematic plan view of a first element region in FIG. 1.

FIG. 3 is a cross-sectional view taken along line III-III in FIG. 2.

FIG. 4 is a cross-sectional view for explaining a modification of a diffusion region in FIG. 3.

FIG. 5 is a cross-sectional view for explaining another modification of the diffusion region in FIG. 3.

FIG. 6 is a cross-sectional view for explaining a configuration of a p-channel JFET according to a comparative example.

FIG. 7 is a graph showing a simulation result of gate currents with respect to absolute values of drain-source voltages Vds.

FIG. 8 is a flowchart showing part of a manufacturing process of the semiconductor device shown in FIGS. 2 and 3.

FIG. 9 is a schematic plan view for explaining an n-channel JFET according to an embodiment of the present disclosure.

FIG. 10 is a cross-sectional view taken along line X-X in FIG. 9.

FIG. 11 is a cross-sectional view for explaining a modification of a diffusion region in FIG. 10.

FIG. 12 is a cross-sectional view for explaining another modification of the diffusion region in FIG. 10.

FIG. 13 is a flowchart showing part of a manufacturing process of the n-channel JFET shown in FIGS. 9 and 10.

The above-mentioned and other objects, features, and effects of the present disclosure will be made clear by the following description of the embodiments with reference to the accompanying drawings.

### DETAILED DESCRIPTION OF THE EMBODIMENTS

Next, embodiments of the present disclosure will be described in detail with reference to the accompanying drawings.

### [Overall Configuration of a Semiconductor Device 1]

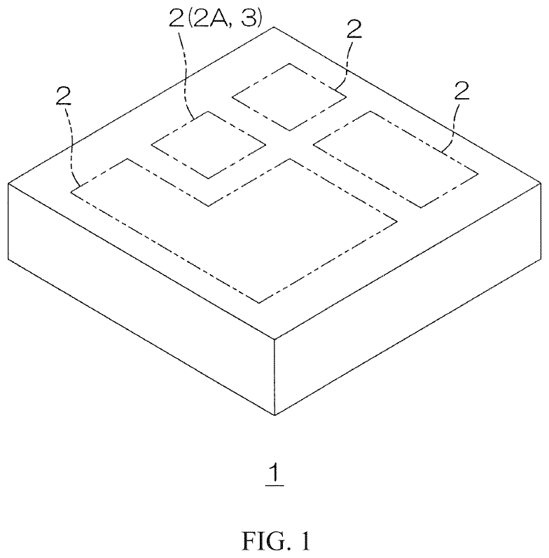

FIG. 1 is a schematic perspective view of the semiconductor device 1 according to an embodiment of the present disclosure.

The semiconductor device 1 includes, for example, a chip-shaped integrated circuit (IC) device. The semiconductor device 1 is classified into a small scale IC (SSI), a middle scale IC (MSI), a large scale IC (LSI), a very large scale IC (VLSI) and an ultra large scale IC (ULSI) based on the number of integrated circuit elements.

The semiconductor device 1 includes a plurality of element regions 2 in which circuit elements are formed. Each of the plurality of element regions 2 is a region in which a functional device is formed, and is insulated and separated from other element regions. The functional device may include, for example, at least one of a semiconductor switching device, a semiconductor rectifying device and a passive device. The functional device may include, for example, a circuitry combining at least two of a semiconductor switching device, a semiconductor rectifying device and a passive device.

The semiconductor switching device includes, for example, at least one of a Metal Oxide Semiconductor Field Effect Transistor (MOSFET), a Bipolar Junction Transistor (BJT), an Insulated Gate Bipolar Junction Transistor (IGBT) and a Junction Field Effect Transistor (JFET). The semiconductor rectifier device may include, for example, at least one of a pn junction diode, a pin junction diode, a Zener diode, a Schottky barrier diode and a fast recovery diode. The passive device may include, for example, at least one of a resistor, a capacitor and an inductor.

In this embodiment, the plurality of element regions 2 include a first element region 2A. The first element region 2A may be a JFET element region in which a p-channel JFET 3 is formed as a circuit element. Although four element regions 2 are shown in FIG. 1, the semiconductor device 1 may have a greater number of element regions.

[Structure of the p-channel JFET 3]

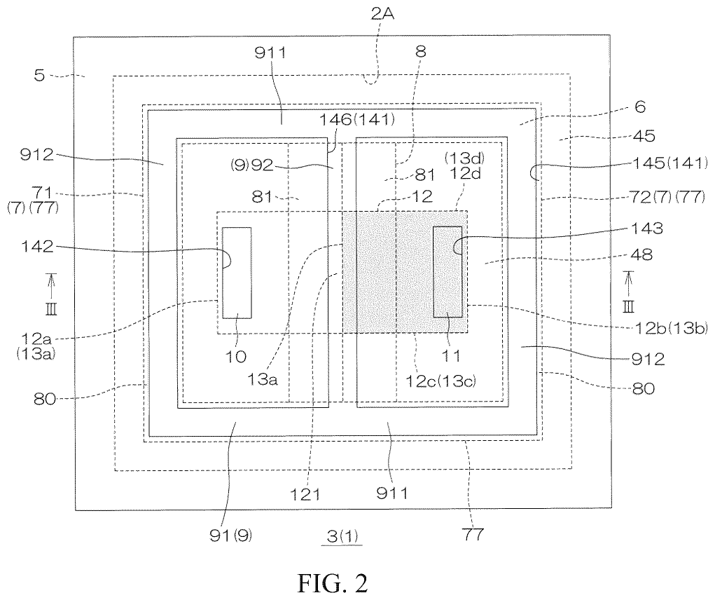

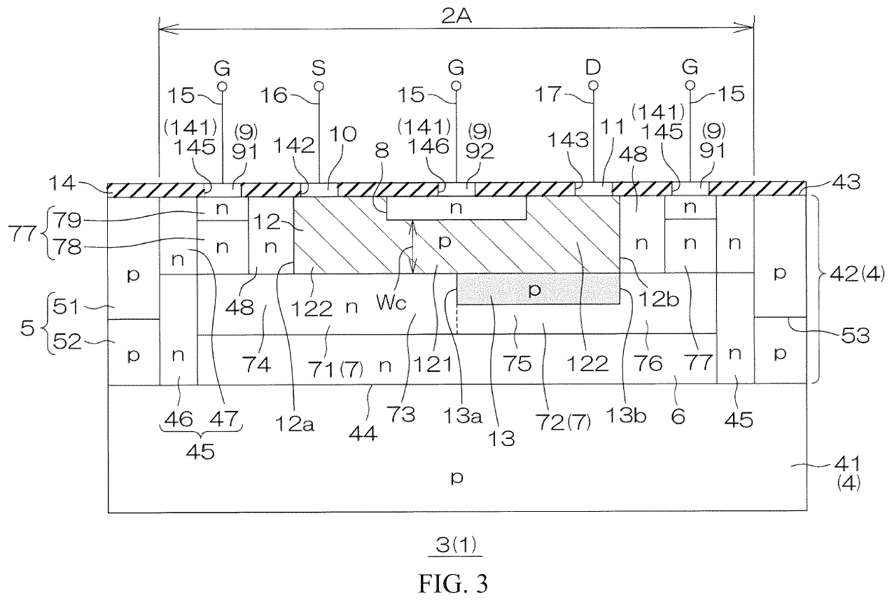

FIG. 2 is a schematic plan view of the first element region 2A (the p-channel JFET 3) in FIG. 1. FIG. 3 is a cross-sectional view taken along line III-III in FIG. 2.

The semiconductor device 1 (the p-channel JFET 3) includes a semiconductor substrate 4, an element isolation portion 5, a buried layer 6, a bottom gate region 7, a top gate region 8, a gate contact region 9, a source region 10, a drain region 11, a channel region 12, a diffusion region 13 and a field insulating film 14. In FIG. 3, the channel region 12 is selectively hatched to aid in understanding the structure.

The semiconductor substrate 4 may include a base substrate 41 and an epitaxial layer 42 as an example of a semiconductor layer.

Although the base substrate 41 is formed of a silicon (Si) substrate in this embodiment, it may be a substrate formed of other materials (for example, silicon carbide (SiC), etc.). In this embodiment, the base substrate 41 is p-type. The base substrate 41 may have an impurity concentration, for example, between about 1×10¹⁴ cm³ and about 5×101 cm⁻³. Moreover, a thickness of the base substrate 41 may be, for example, between about 500 μm and about 800 μm before grinding.

The epitaxial layer 42 is in contact with the base substrate 41 and is stacked on the base substrate 41. The epitaxial layer 42 has an element main surface 43 and a bonding surface 44 facing opposite to the element main surface 43 in a thickness direction of the epitaxial layer 42. The element main surface 43 is a surface on which an element region 2 (the first element region 2A in FIGS. 2 and 3) is formed. The bonding surface 44 is a surface in contact with the base substrate 41. In this embodiment, the epitaxial layer 42 has a conductivity type opposite to that of the base substrate 41, and is n-type in this embodiment. The epitaxial layer 42 may have an n-type impurity concentration lower than that of the base substrate 41. The epitaxial layer 42 may have the n-type impurity concentration, for example, between about 5×10⁴ cm⁻³ and about 1×10⁷ cm⁻³. Moreover, a thickness of the epitaxial layer 42 may be, for example, 3 μm to 20 μm.

The element isolation portion 5 may include an element isolation well. More specifically, as shown in FIGS. 2 and 3, in the plan view, a band-shaped p-type element isolation well that draws a closed curve may be formed to reach the base substrate 41 from the element main surface 43 of the epitaxial layer 42. In this embodiment, the element isolation portion 5 is formed in a square annular shape in the plan view as shown in FIG. 2, but it may have another closed curve structure such as a circular ring shape or a triangular ring shape.

Referring to FIG. 3, the element isolation portion 5 may have a two-layer structure including a p-type well region 51 disposed on an upper side and a p-type low isolation (L/I) region 52 disposed on a lower side. An impurity concentration of the low isolation region 52 may be greater than that of the well region 51. A boundary 53 between the regions 51 and 52 may be disposed in a middle of the epitaxial layer 42 in the thickness direction. Therefore, the first element region 2A is defined in the semiconductor substrate 4, which is formed of a portion of the epitaxial layer 42 surrounded by the element isolation portion 5 on the base substrate 41.

As shown in FIG. 2, the n-type buried layer 6 (B/L) is formed in an island shape in the plan view. The buried layer 6 is surrounded by an n-type outer epitaxial region 45 of the epitaxial layer 42. In this embodiment, the outer epitaxial region 45 has a lower region 46 and an upper region 47. The upper region 47 may have an n-type impurity concentration different from that of the lower region 46.

In this embodiment, the buried layer 6 is formed in a rectangular shape in the plan view as shown in FIG. 2, but it may have another planar structure such as a circular shape or a triangular shape. Moreover, the buried layer 6 is selectively buried in the first element region 2A, as shown in FIG. 3. The buried layer 6 is formed at a boundary between the base substrate 41 and the epitaxial layer 42 in the semiconductor substrate 4. The buried layer 6 may be across the boundary between the base substrate 41 and the epitaxial layer 42, and may be partially buried in the base substrate 41. A thickness of the buried layer 6 may be, for example, 1.0 μm to 10 μm.

As shown in FIG. 2, the bottom gate region 7 is formed in an island shape in the plan view. In this embodiment, the bottom gate region 7 is formed in a rectangular shape in the plan view as shown in FIG. 2, but it may have another planar structure such as a circular shape or a triangular shape.

Referring to FIG. 3, the bottom gate region 7 is formed away from the element main surface 43 of the epitaxial layer 42 toward a side of the bonding surface 44. In this embodiment, the bottom gate region 7 is surrounded by the outer epitaxial region 45 with a bottom of the bottom gate region 7 in contact with the buried layer 6 in the thickness direction of the epitaxial layer 42.

In this embodiment, the bottom gate region 7 is n-type. In this embodiment, the bottom gate region 7 has an n-type impurity concentration greater than that of the outer epitaxial region 45 (the epitaxial layer 42). In this embodiment, the n-type impurity concentration of the bottom gate region 7 is less than an n-type impurity concentration of the buried layer 6. Note that the bottom gate region 7 may have the same n-type impurity concentration as that of the outer epitaxial region 45 (the epitaxial layer 42). The n-type impurity concentration of the bottom gate region 7 is preferably between about 5×10¹⁴ cm⁻³ and about 5×10¹⁸ cm⁻³.

As shown in FIG. 2, the top gate region 8 is formed in a linear shape in the plan view. In this embodiment, the top gate region 8 extends in a direction that divides the island-shaped bottom gate region 7, as shown in FIG. 2. The bottom gate region 7 has a first bottom gate region 71 and a second bottom gate region 72 separated by the top gate region 8 in the plan view. That is, the bottom gate region 7 has the first bottom gate region 71 on a source region 10 side and the second bottom gate region 72 on a drain region 11 side.

Referring to FIG. 3, the top gate region 8 is formed in a surface layer portion of the element main surface 43 of the epitaxial layer 42. The top gate region 8 faces the bottom gate region 7 in the thickness direction of the epitaxial layer 42. In this embodiment, the top gate region 8 is n-type. In this embodiment, an impurity concentration of the top gate region 8 is greater than the impurity concentration of the bottom gate region 7. Note that the impurity concentration of the top gate region 8 may be the same as the n-type impurity concentration of the bottom gate region 7 or may be less than the n-type impurity concentration of the bottom gate region 7. The n-type impurity concentration of the top gate region 8 is preferably between about 5×10¹⁴ cm⁻³ and about 5×10¹⁸ cm⁻³.

The first bottom gate region 71 may integrally include a first gate opposing portion 73 and a first gate extending portion 74. The first gate opposing portion 73 may be a region that faces a region of the top gate region 8 on the source region 10 side in the thickness direction of the epitaxial layer 42. The first gate extending portion 74 extends from the first gate opposing portion 73 toward the source region 10 in a direction along the element main surface 43. Since the first gate extending portion 74 does not face the top gate region 8 in the thickness direction of the epitaxial layer 42, it may also be referred to as a first gate non-opposing portion.

The second bottom gate region 72 may integrally include a second gate opposing portion 75 and a second gate extending portion 76. The second gate opposing portion 75 may be a region that faces a region of the top gate region 8 on the drain region 11 side in the thickness direction of the epitaxial layer 42. The second gate extending portion 76 extends from the second gate opposing portion 75 toward the drain region 11 in the direction along the element main surface 43. Since the second gate extending portion 76 does not face the top gate region 8 in the thickness direction of the epitaxial layer 42, it may also be referred to as a second gate non-opposing portion.

In this embodiment, the gate contact region 9 is n-type and has an impurity concentration greater than those of the bottom gate region 7, the top gate region 8 and the buried layer 6. As shown in FIGS. 2 and 3, the gate contact region 9 is formed in the surface layer portion of the element main surface 43 of the epitaxial layer 42.

The gate contact region 9 integrally includes a first gate contact portion 91 electrically connected to the bottom gate region 7 and a second gate contact portion 92 electrically connected to the top gate region 8.

Referring to FIG. 2, the first gate contact portion 91 is formed in an annular shape along a peripheral edge portion of the bottom gate region 7. In this embodiment, the first gate contact portion 91 is formed in a rectangular ring shape including a pair of first linear portions 911 facing each other and a pair of second linear portions 912 facing each other in the plan view. The first linear portions 911 and the second linear portions 912 may be orthogonal to each other.

Referring to FIG. 3, a gate middle region 77 is formed between the first gate contact portion 91 and the peripheral edge portion of the bottom gate region 7 (the first gate extending portion 74 and the second gate extending portion 76). In this embodiment, the gate middle region 77 is n-type and has an n-type impurity concentration less than that of the top gate region 8. Note that the gate middle region 77 may have an n-type impurity concentration greater than that of the top gate region 8. Moreover, the gate middle region 77 may be composed of the epitaxial layer 42 similarly to the outer epitaxial region 45 and an inner epitaxial region 48. Furthermore, the gate middle region 77 may have the n-type impurity concentration less than that of the epitaxial layer 42.

Therefore, as shown in FIG. 3, the inner epitaxial region 48 is formed in the epitaxial layer 42 and is formed of a portion of the epitaxial layer 42 which is surrounded by the bottom gate region 7, the first gate contact portion 91 and the gate middle region 77. Same as the outer epitaxial region 45, the inner epitaxial region 48 is a region in which the impurity concentration of the epitaxial layer 42 is maintained.

The gate middle region 77 includes a lower middle region 78 disposed at a lower side and an upper middle region 79 disposed at an upper side. An n-type impurity concentration of the lower middle region 78 may be less than an n-type impurity concentration of the upper middle region 79. The n-type impurity concentration of the lower middle region 78 may be greater than the n-type impurity concentration of the upper middle region 79. Moreover, the n-type impurity concentration of the upper middle region 78 may be the same as the n-type impurity concentration of the upper middle region 79.

The gate middle region 77 is physically and electrically connected to both the first gate contact portion 91 and the peripheral edge portion of the bottom gate region 7 (the first gate extending portion 74 and the second gate extending portion 76) and sandwiched between the first gate contact portion 91 and the peripheral edge portion of the bottom gate region 7 from above and below. Therefore, the first gate contact portion 91 (the gate contact region 9) is electrically connected to the bottom gate region 7 via the gate middle region 77.

Moreover, referring to FIG. 2, the gate middle region 77 is formed in a ring shape (in this embodiment, a square annular shape) along the first gate contact portion 91. The gate middle region 77 may have a width wider than that of the first gate contact portion 91 in the plan view. Therefore, the gate middle region 77 may include drawn-out portions 80 drawn out from both sides of the first gate contact portion 91 in a width direction. In this embodiment, the annular gate middle region 77 has the drawn-out portions 80 on both sides, inside and outside the ring.

Referring to FIG. 2, the second gate contact portion 92 is formed across multiple locations of the first gate contact portion 91 so as to divide the bottom gate region 7. In this embodiment, the second gate contact portion 92 is formed in a straight line that connects the pair of first linear portions 911. The second gate contact portion 92 is formed on the top gate region 8 and has a linear shape along the top gate region 8. Therefore, in the plan view, the first bottom gate region 71 and the second bottom gate region 72 may be laterally separated from each other by the second gate contact portion 92. In this embodiment, the second gate contact portion 92 is located directly above a boundary between the first bottom gate region 71 and the second bottom gate region 72.

Note that the top gate region 8 may have a width wider than that of the second gate contact portion 92 in the plan view. Therefore, the top gate region 8 may include drawn-out portions 81 drawn out from both sides of the second gate contact portion 92 in the width direction. The second gate contact portion 92 is physically and electrically connected to the top gate region 8. Therefore, the gate contact region 9 including the first gate contact portion 91 and the second gate contact portion 92 is electrically connected in common with the bottom gate region 7 and the top gate region 8.

In this embodiment, the source region 10 is p-type. As shown in FIGS. 2 and 3, the source region 10 is formed in the surface layer portion of the element main surface 43 of the epitaxial layer 42. Referring to FIG. 2, the source region 10 is formed on the first bottom gate region 71 and is separated from the top gate region 8 in a direction along element main surface 43.

The source region 10 is formed near a center of the first bottom gate region 71 in a direction perpendicular to the top gate region 8 (the left-right direction in the paper plane of FIG. 3). The source region 10 may be formed on a side closer to the top gate region 8 or on a side farther from the top gate region 8 than the center of the first bottom gate region 71 in the direction perpendicular to the top gate region 8.

In this embodiment, the drain region 11 is p-type. As shown in FIGS. 2 and 3, the drain region 11 is formed in the surface layer portion of the element main surface 43 of the epitaxial layer 42. Referring to FIG. 2, the drain region 11 is formed on the second bottom gate region 72 and is separated from the top gate region 8 on an opposite side of the source region 10 in the direction along the element main surface 43.

The drain region 11 is formed near a center of the second bottom gate region 72 in the direction perpendicular to the top gate region 8. The drain region 11 may be formed on a side closer to the top gate region 8 or on a side farther from the top gate region 8 than the center of second bottom gate region 72 in the direction perpendicular to top gate region 8.

Referring to FIG. 2, the channel region 12 is formed between the source region 10 and the drain region 11 in the direction along the element main surface 43. For example, the channel region 12 may be formed approximately in a center between the source region 10 and the drain region 11.

In the plan view, the channel region 12 has a rectangular shape with two sides 12a and 12b that face each other in the direction perpendicular to the top gate region 8 (the left-right direction in the paper plane of FIG. 3) and with two sides 12c and 12d that face each other in a direction in which the top gate region 8 extends (the up-down direction in the paper plane of FIG. 3).

Referring to FIG. 3, the channel region 12 is formed between the bottom gate region 7 and the top gate region 8 in the thickness direction of the epitaxial layer 42.

In this embodiment, the channel region 12 is p-type. The channel region 12 has a p-type impurity concentration less than those of the source region 10 and the drain region 11. The p-type impurity concentration of the channel region 12 is preferably between about 5×10¹⁴ cm⁻³ and about 5×10¹⁸ cm⁻³. A width We of the channel region 12 in the thickness direction of the epitaxial layer 42 may be, for example, between about 0.2 μm and about 2 m.

In this embodiment, the channel region 12 is in contact with the top gate region 8 and forms an interface between the channel region 12 and the top gate region 8. Moreover, the channel region 12 is in contact with the bottom gate region 7. Therefore, an npn structure is formed in which the p-type channel region 12 is sandwiched between the n-type gate regions 7 and 8 from upper and lower sides. The npn structure forms a p-channel junction field effect transistor (the p-channel JFET 3).

Note that the channel region 12 may be separated from one or both of the bottom gate region 7 and the top gate region 8.

The channel region 12 may include a channel portion 121 and a channel peripheral portion 122. The channel portion 121 is a portion sandwiched between the top gate region 8 and the bottom gate region 7 below the top gate region 8. The channel peripheral portion 122 may be formed outside the top gate region 8 in the plan view, and may be a portion surrounding both the top gate region 8 and the channel portion 121.

The diffusion region 13 is formed in a surface layer portion of the bottom gate region 7 and in a region of the source region 10 and the drain region 11 that is biased toward the drain region 11 side. In FIGS. 2 and 3, the diffusion region 13 is shown in gray for clarity. The diffusion region 13 is p-type. In this embodiment, the diffusion region 13 has the same p-type impurity concentration as that of the channel region 12. The p-type impurity concentration of the diffusion region 13 is preferably between about 5×10¹⁴ cm⁻³ and about 5×10¹⁸ cm⁻³.

As shown in FIG. 2, in the plan view, the diffusion region 13 has a rectangular shape with two sides 13a, 13b parallel to the two sides 12a, 12b of the channel region 12 and with two sides 13c, 13d parallel to the two sides 12c, 12d of the channel region 12.

In this embodiment, the side 13a of the diffusion region 13 is aligned with a side edge of the second bottom gate region 72 on the source region 10 side (the boundary between the first bottom gate region 71 and the second bottom gate region 72) in the plan view. The side 13b of the diffusion region 13 is aligned with the side 12b of the channel region 12 on the drain region 11 side in the plan view. The side 13c of the diffusion region 13 is aligned with the side 12c of the channel region 12 in the plan view. The side 13d of the diffusion region 13 is aligned with the side 12d of the channel region 12 in the plan view.

That is, in this embodiment, the diffusion region 13 is formed in a region from the side edge of the second bottom gate region 72 on the source region 10 side to a side edge of the channel region 12 on the drain region 11 side in the direction perpendicular to the top gate region 8.

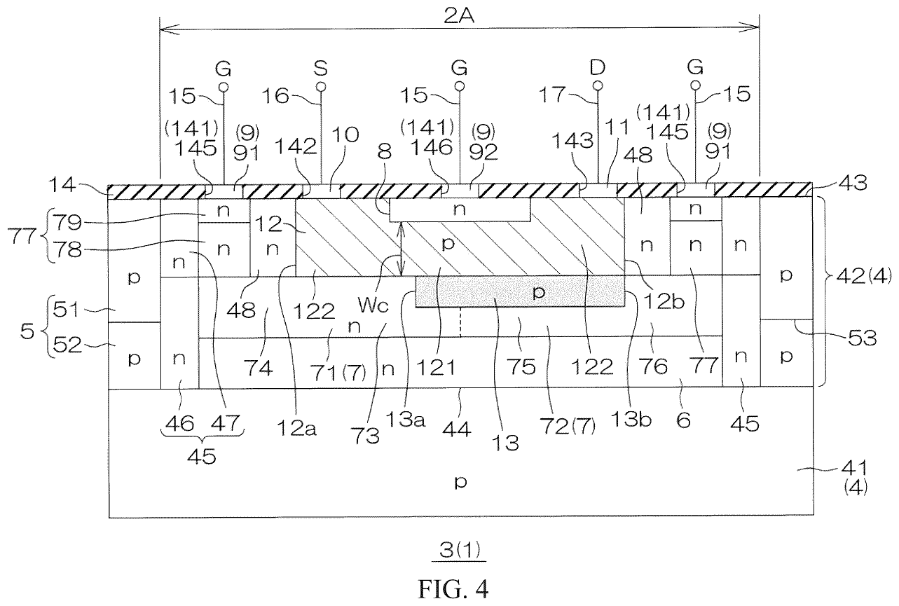

As shown in FIG. 4, in the plan view, the side 13a of the diffusion region 13 on the source region 10 side may be disposed between the side edge of the second bottom gate region 72 on the source region 10 side and a side edge of the source region 10 on the drain region 11 side.

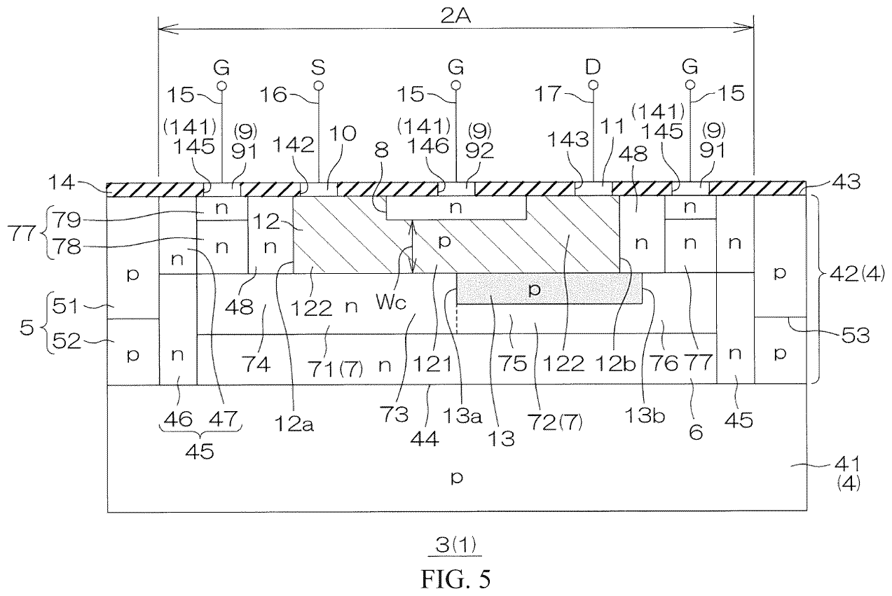

Moreover, as shown in FIG. 5, in the plan view, the side 13b of the diffusion region 13 on the drain region 11 side may be disposed between the side edge of the second bottom gate region 72 on the drain region 11 side and the gate middle region 77 (the second linear portions 912) on the drain region 11 side.

In this embodiment, the diffusion region 13 is formed in a region from the side 12c to the side 12d of the channel region 12 along the direction in which the top gate region 8 extends. In other words, in this embodiment, a length of the diffusion region 13 along the direction in which the top gate region 8 extends is equal to a length of the channel region 12 in such direction.

In the plan view, the sides 13c and 13d of the diffusion region 13 may extend further to an outside of the channel region 12 than the corresponding sides 12c and 12d of the channel region 12, respectively. In other words, the length of the diffusion region 13 along the direction in which the top gate region 8 extends may be greater than the length of the channel region 12 in such direction.

In the plan view, the diffusion region 13 does not exist in a region opposite to the drain region 11 side with respect to the side edge of the source region 10 on the drain region 11 side, while it preferably exists in a region including a region directly below the drain region 11.

In the plan view, the diffusion region 13 does not exist in a region opposite to the drain region 11 side with respect to the side edge of the source region 10 on the drain region 11 side, while it preferably exists in a region including a region between the side edge of the top gate region 8 on the drain region 11 side and the side edge of the channel region 12 on the drain region 11 side.

In the plan view, the diffusion region 13 does not exist in a region opposite to the drain region 11 side with respect to the side edge of the source region 10 on the drain region 11 side, while it preferably exists in a region including a region between a center position between the source region 10 and the drain region 11 in the top gate region 8 and the side edge on the drain region 11 side in the channel region 12.

The field insulating film 14 is formed on the element main surface 43 of the epitaxial layer 42. The field insulating film 14 may be, for example, a LOCOS film (silicon oxide film) formed by selectively oxidizing the element main surface 43. The field insulating film 14 has a gate opening 141 that exposes the gate contact region 9, a source opening 142 that exposes the source region 10 and a drain opening 143 that exposes the drain region 11.

The gate opening 141 has the same planar shape as the gate contact region 9. The gate opening 141 includes a first opening 145 that exposes the first gate contact portion 91 and a second opening 146 that exposes the second gate contact portion 92. The first opening 145 is formed in an annular shape along the annular first gate contact portion 91. The second opening 146 is formed across multiple locations of the first openings 145 so as to divide the bottom gate region 7.

The source opening 142 has the same planar shape as the source region 10. The drain opening 143 has the same planar shape as the drain region 11.

Wirings are connected to the impurity regions exposed through the openings 141 to 143, 145 and 146. For example, a gate wiring 15 may be connected to the gate contact region 9, a source wiring 16 may be connected to the source region 10 and a drain wiring 17 may be connected to the drain region 11.

### Effects of this Embodiment

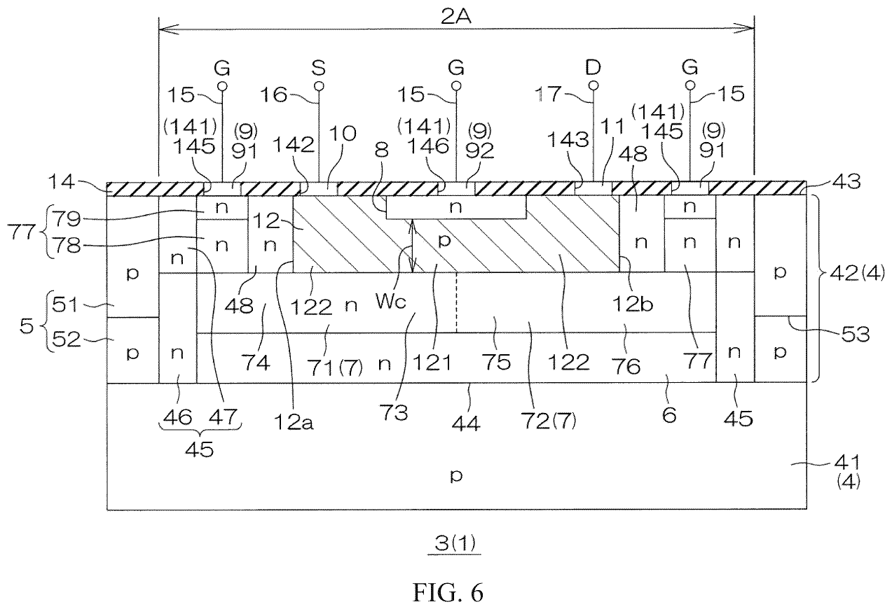

FIG. 6 is a cross-sectional view for explaining the configuration of a p-channel JFET 103 according to a comparative example, and is a cross-sectional view corresponding to the cross-sectional view of FIG. 3. In FIG. 6, elements corresponding to those in FIG. 3 are designated by the same reference numerals as in FIG. 3.

The p-channel JFET 103 according to the comparative example differs from the p-channel JFET 3 according to the present embodiment only in that the diffusion region 13 is not formed.

The operation of the p-channel JFET 103 will be explained. When a voltage is applied with the drain wiring 17 as a low potential side and the source wiring 16 as a high potential side, conduction occurs between the source region 10 and the drain region 11 via the channel region 12. At this time, if no control voltage (gate voltage) is applied to the gate wiring 15, or if a control voltage (gate voltage) that is positive relative to the source potential to an extent such that the channel region is not blocked by the depletion layer is applied, a pn junction between the p-type channel region 12 and the n-type bottom gate region 7, and a pn junction between the p-type channel region 12 and the n-type top gate region 8 will not extend out a sufficiently wide depletion layer.

That is, a current flowing through the channel region 12 in the direction along the element main surface 43 is not blocked by the depletion layer, and the p-channel JFET 103 is in an on state (normally on). On the other hand, if a gate voltage that is positive relative to the source potential that is higher than that at which the depletion layer can fully spread within the channel region 12 is applied to the gate wiring 15, it becomes difficult for holes to move within the channel region 12. As a result, the depletion layer blocks the movement of holes in the channel region 12. That is, the p-channel JFET 103 is turned off. The gate voltage at this time is defined as a cut-off voltage.

Even if the required value of the cut-off voltage is around 1V, in the p-channel JFET 103 when a voltage of several tens of volts (for example, about 36V) is applied between the drain and source, under voltage conditions that an absolute value of a drain-source voltage Vds is 1V or more and a source-gate voltage Vgs is 0V, the channel region 12 on the drain region 11 side will still be pinched off. In this situation, as the absolute value of the drain-source voltage Vds further increases, an electric field strength near the drain region 11 increases. Then, an impact ionization phenomenon (impact ionization) occurs due to holes moving from the source region 10 side to the drain region 11 side, and electron-hole pairs are generated. Since the charges (electrons) generated at this time flow to the gate regions 7 and 8, the gate current becomes large.

In the p-channel JFET 3 according to this embodiment, the diffusion region 13 is formed in the surface layer portion of the bottom gate region 7 and in a region of the source region 10 and the drain region 11 that is biased toward the drain region 11 side. This makes it possible to suppress an occurrence of impact ionization, thereby reducing the gate current. The reason for this will be explained below.

The cut-off voltage of the p-channel JFET 3 is determined by the spread of the depletion layer on the source region 10 side. The electric field strength when a high voltage is applied between the drain and source is determined by the spread of the depletion layer on the drain region 11 side.

In this embodiment, since the diffusion region 13 is formed on the drain region 11 side in the surface layer portion of the bottom gate region 7, the depletion layer is difficult to expand on the drain region 11 side. Therefore, the electric field strength can be suppressed while the cut-off voltage remains low, so that the occurrence of impact ionization phenomenon can be suppressed. As a result, the gate current can be reduced.

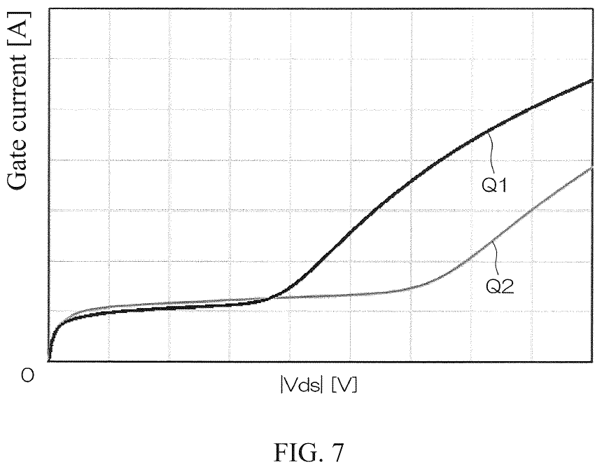

FIG. 7 is a graph showing a simulation result of gate currents with respect to absolute values |Vds| of drain-source voltages Vds (for example, 0 to −36 V).

In FIG. 7, Q1 is a graph showing a simulation result for the comparative example, and Q2 is a graph showing a simulation result for the p-channel JFET 3 according to the present embodiment.

From FIG. 7, it can be seen that the p-channel JFET 3 according to the present embodiment can reduce the gate current when the absolute values of the drain-source voltages Vds are large compared to the comparative example.

Furthermore, in this embodiment, a cross-sectional area of an electron movement path is larger in a region on the drain region side than that in the comparative example, so that the drain current relative to the drain-source voltage can be increased.

### [Method for Manufacturing the Semiconductor Device 1]

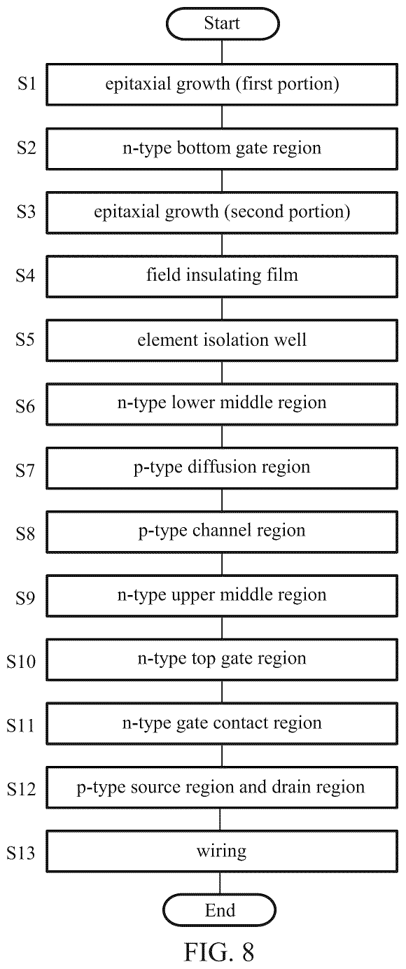

FIG. 8 is a flowchart showing part of a manufacturing process of the semiconductor device 1. Next, an example of the manufacturing process of the semiconductor device 1 will be described with reference to FIG. 8.

To fabricate the semiconductor device 1, first, a p-type base substrate 41 is prepared. Next, n-type impurities and p-type impurities are selectively implanted into a surface of the base substrate 41. Next, silicon of the base substrate 41 is epitaxially grown while adding n-type impurities (step S1). Thus, a semiconductor substrate 4 including the p-type base substrate 41 and a first portion of an epitaxial layer 42 is formed. The first portion includes a region where a bottom gate region 7 is to be formed.

During the epitaxial growth of the base substrate 41, the n-type impurities and the p-type impurities implanted into the base substrate 41 diffuse in a growth direction of the epitaxial layer 42. Therefore, a buried layer 6 and a p-type low isolation region 52 are formed at a boundary between the base substrate 41 and the epitaxial layer 42.

Next, an ion implantation mask having an opening selectively disposed in a region where the bottom gate region 7 is to be formed is formed on the epitaxial layer 42 (the first portion). Then, n-type impurities are implanted into the epitaxial layer 42 through such ion implantation mask (step S2). Therefore, the n-type bottom gate region 7 is formed on the buried layer 6.

Next, p-type impurities for forming a portion of a well region 51 are selectively implanted into a surface of the epitaxial layer 42 (the first portion). Then, the silicon of the base substrate 41 is further epitaxially grown while adding the n-type impurities (step S3). Therefore, a second portion of the epitaxial layer 42 is formed. As a result, the epitaxial layer 42 having an element main surface 43 and a bonding surface 44 is obtained.

Next, a field insulating film 14 is formed on the element main surface 43 of the epitaxial layer 42 (step S4).

Next, an ion implantation mask having an opening selectively disposed in a region where the p-type well region 51 is to be formed is formed on the field insulating film 14. Then, p-type impurities are implanted into the epitaxial layer 42 through such ion implantation mask (step S5).

Therefore, an element isolation portion 5 (an element isolation well) having a two-layer structure of the p-type well region 51 and the p-type low isolation region 52 is formed.

Next, an ion implantation mask having an opening selectively disposed in a region where a gate middle region 77 is to be formed is formed on the field insulating film 14. Then, n-type impurities are implanted into the epitaxial layer 42 through such ion implantation mask (step S6). Therefore, a lower middle region 78 of the gate middle region 77 is formed.

Next, an ion implantation mask having an opening selectively disposed in a region where a diffusion region 13 is to be formed is formed on the field insulating film 14. Then, p-type impurities are implanted into the epitaxial layer 42 through such ion implantation mask (step S7). Therefore, the p-type diffusion region 13 is formed.

Next, an ion implantation mask having an opening selectively disposed in a region where a channel region 12 is to be formed is formed on the field insulating film 14. Then, p-type impurities are implanted into the epitaxial layer 42 through such ion implantation mask (step S8). Therefore, the p-type channel region 12 is formed.

Next, an ion implantation mask having an opening selectively disposed in a region where the gate middle region 77 is to be formed is formed on the field insulating film 14. Then, n-type impurities are implanted into the epitaxial layer 42 through such ion implantation mask (step S9). Therefore, an upper middle region 79 of the gate middle region 77 is formed.

Next, an ion implantation mask having an opening selectively disposed in a region where a top gate region 8 is to be formed is formed on the field insulating film 14. Then, n-type impurities are implanted into the epitaxial layer 42 through such ion implantation mask (step S10). Therefore, the n-type top gate region 8 is formed.

Next, an ion implantation mask having an opening selectively disposed in a region where a gate contact region 9 is to be formed is formed on the field insulating film 14. Then, n-type impurities are implanted into the epitaxial layer 42 through such ion implantation mask (step S11). Therefore, the n-type gate contact region 9 is formed.

Next, an ion implantation mask having openings selectively disposed in regions where a source region 10 and a drain region 11 are to be formed is formed on the field insulating film 14. Then, p-type impurities are implanted into the epitaxial layer 42 through such ion implantation mask (step S12). Therefore, the p-type source region 10 and the p-type drain region 11 are formed.

Next, the semiconductor device 1 described above is obtained by performing a step of forming wirings 15 to 17 (step S13) and the like.

Note that the manufacturing process of the semiconductor device 1 described using FIG. 8 as an example, and the semiconductor device 1 may be manufactured by other manufacturing processes. For example, in the embodiments described above, the epitaxial layer 42 is formed in two stages, but the epitaxial layer 42 does not need to be formed in two stages. That is, in step S1, the epitaxial layer 42 having the element main surface 43 and the bonding surface 44 may be formed on the base substrate 41. In this case, the bottom gate region 7, an outer epitaxial region 45 and an inner epitaxial region 48 may have the same n-type impurity concentration.

Moreover, in the embodiments described above, the n-type bottom gate region 7 is formed by implanting n-type impurities into the epitaxial layer 42 after step S1. However, after the field insulating film 14 is formed in step S4 and until the element isolation portion 5 is formed in step S5, a highly accelerated ion implantation is performed, so that the n-type bottom gate region 7 may be formed.

[Structure of an n-Channel JFET 3A]

In the embodiments described above, the semiconductor device 1 in which the p-channel JFET 3 is formed in a first element region 2A has been described, but the n-channel JFET 3A may be formed in the first element region 2A.

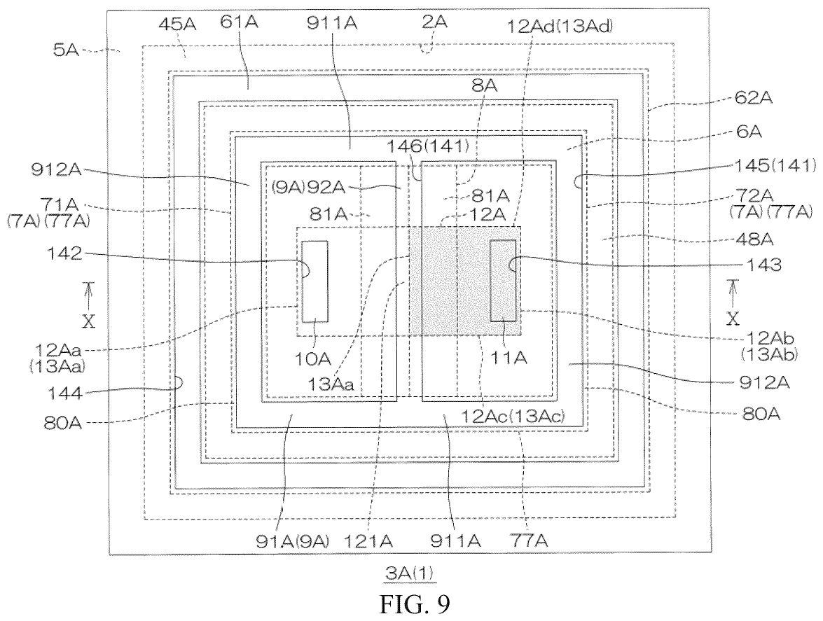

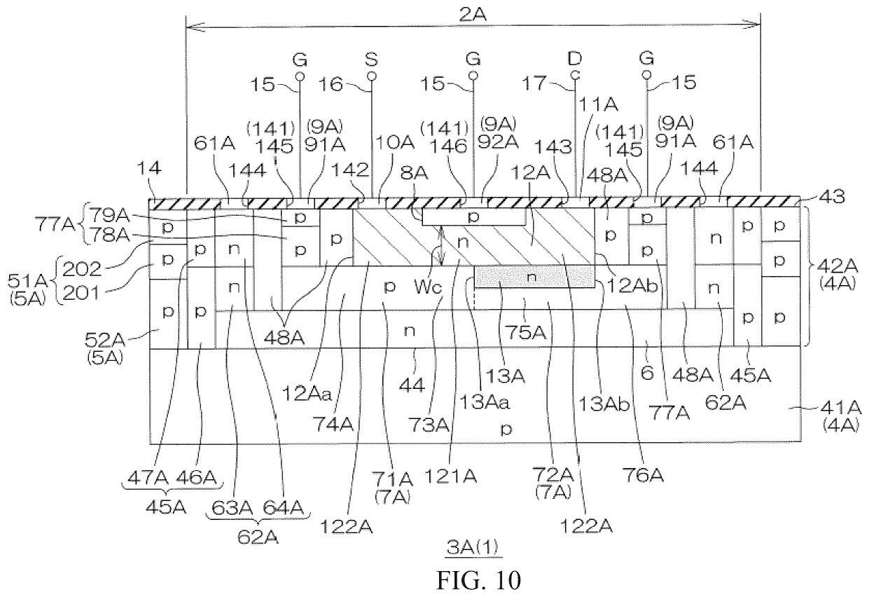

FIG. 9 is a schematic plan view of the n-channel JFET 3A. FIG. 10 is a cross-sectional view taken along line X-X in FIG. 9. In FIGS. 9 and 10, elements corresponding to those in FIGS. 2 and 3 described above are denoted by the same reference numerals as in FIGS. 2 and 3.

The n-channel JFET 3A has a different configuration from that of the JFET 3 described above. The n-channel JFET 3A includes a semiconductor substrate 4A, an element isolation portion 5A, a bottom gate region 7A, a top gate region 8A, a gate contact region 9A, a source region 10A, a drain region 11A, a channel region 12A, a diffusion region 13A, an epitaxial layer 42A, a gate middle region 77A, a first contact region 61A and a first middle region 62A.

In FIG. 10, the channel region 12A is selectively hatched to help understand the structure. Furthermore, the diffusion region 13A is shown in gray.

Each of the conductivity types of the bottom gate region 7A, the top gate region 8A, the gate contact region 9A, the source region 10A, the drain region 11A, the channel region 12A, the diffusion region 13A, the epitaxial layer 42A and the gate middle region 77A is different from that of the corresponding portion in the p-channel JFET3 μmentioned above.

Specifically, the bottom gate region 7A, the top gate region 8A, the gate contact region 9A, the epitaxial layer 42A and the gate middle region 77A are p-type. The source region 10A, the drain region 11A, the channel region 12A and the diffusion region 13A are n-type.

Since the bottom gate region 7A, the top gate region 8A, the gate contact region 9A, the source region 10A, the drain region 11A, the channel region 12A, the diffusion region 13A, the epitaxial layer 42A and the gate middle region 77A have substantially the same shape (planar shape and cross-sectional shape) as the corresponding portions in the aforementioned p-channel JFET 3, detailed explanation thereof will be omitted.

The element isolation portion 5A is p-type, like the element isolation portion 5 of the p-channel JFET 3. The base substrate 41 is p-type, like the base substrate 41 of the p-channel JFET 3. The buried layer 6 is n-type, like the buried layer 6 of the p-channel JFET 3.

In this embodiment, the element isolation portion 5A has a two-layer structure including a p-type well region 51A disposed on an upper side and a p-type low isolation (L/I) region 52A disposed on a lower side. A p-type impurity concentration of the low isolation region 52A may be greater than a p-type impurity concentration of the well region 51A, or may be the same as the p-type impurity concentration of the well region 51A.

In this embodiment, the well region 51A includes a lower well region 201 located on the lower side and an upper well region 202 located on the upper side. In this embodiment, a p-type impurity concentration of the lower well region 201 is the same as a p-type impurity concentration of a lower middle region 78A. Furthermore, a p-type impurity concentration of the upper well region 202 may be the same as a p-type impurity concentration of an upper middle region 79A.

The epitaxial layer 42A is p-type. The buried layer 6is surrounded by an outer epitaxial region 45A of the epitaxial layer 42A.

The first contact region 61A is n-type and has an impurity concentration greater than that of the buried layer 6. As shown in FIGS. 9 and 10, the first contact region 61A is formed in a surface layer portion of the element main surface 43 of the epitaxial layer 42A, and has an annular shape (in this embodiment, a square annular shape) along a peripheral edge of the buried layer 6 in the plan view. The first contact region 61A is formed surrounding a first gate contact portion 91A and spaced apart from the first gate contact portion 91A. In addition to openings 141, 142, 143, 145, and 146, the field insulating film 14 has a first contact opening 144 that exposes the first contact region 61A. The first contact opening 144 has the same planar shape as that of the first contact region 61. The first contact opening 144 is formed in an annular shape along the annular first contact region 61.

The first middle region 62A may have a two-layer structure including an n-type lower first middle region 63A disposed on a lower side and an n-type upper first middle region 64A disposed on an upper side. An impurity concentration of the lower first middle region 63A may be less than that of the upper first middle region 64A. An n-type impurity concentration of the first middle region 62A may be between about 5×10¹⁴ cm⁻³ and about 5×10¹⁸ cm⁻³.

The first middle region 62A has an annular shape (in this embodiment, a square annular shape) along the peripheral edge of the buried layer 6 in the plan view. Therefore, in the epitaxial layer 42A, an inner epitaxial region 48A is formed of a portion of the epitaxial layer 42A that is surrounded by the buried layer 6, the first contact region 61A and the first middle region 62A, as shown in FIG. 10. The inner epitaxial region 48A is a region where an impurity concentration of the epitaxial layer 42A is maintained, similar to the outer epitaxial region 45A.

In this embodiment, the bottom gate region 7A is surrounded by the inner epitaxial region 46A with its bottom in contact with the buried layer 6 in a thickness direction of the epitaxial layer 42A.

In this embodiment, a pnp structure is formed in which the n-type channel region 12A is sandwiched between p-type gate regions 7A and 8A from both upper and lower sides. This pnp structure forms an n-channel junction field effect transistor (the n-channel JFET 3A).

In this embodiment, the bottom gate region 7A has the same p-type impurity concentration as the top gate region 8A. In this embodiment, the upper middle region 79A of the gate middle region 77A has the same p-type impurity concentration as the bottom gate region 7A.

In this embodiment, the lower middle region 78A of the gate middle region 77A has a p-type impurity concentration less than that of the upper middle region 79A. Note that the lower middle region 78A may have the same p-type impurity concentration as that of the upper middle region 79A. In this embodiment, the gate contact region 9A has a p-type impurity concentration greater than that of the bottom gate region 7A. In this embodiment, the channel region 12A has an n-type impurity concentration less than that of the buried layer 6A. In this embodiment, the source region 10A and the drain region 11A have an n-type impurity concentration greater than that of the buried layer 6A. In this embodiment, the diffusion region 13A has the same n-type impurity concentration as that of the channel region 12A.

The p-type impurity concentrations of the bottom gate region 7A and the top gate region 8A are preferably between about 5×10¹⁴ cm⁻³ and about 5×10¹⁸ cm⁻³. The n-type impurity concentrations of the channel region 12A and the diffusion region 13A are preferably between about 5×10¹⁴ cm⁻³ and about 5×10¹⁸ cm⁻³.

The diffusion region 13A is formed in a surface layer portion of the bottom gate region 7A and in a region of the source region 10A and the drain region 11A that is biased toward the drain region 11A side. As shown in FIG. 9, in the plan view, the diffusion region 13A has a rectangular shape with two sides 13Aa and 13Ab parallel to two sides 12Aa and 12Ab of the channel region 12A and with two sides 13Ac and 13Ad parallel to two sides 12Ac and 12Ad of the channel region 12A.

In this embodiment, the side 13Aa of the diffusion region 13A is aligned with a side edge of the second bottom gate region 72A on the source region 10A side (a boundary between the first bottom gate region 71A and the second bottom gate region 72A) in the plan view. The side 13Ab of the diffusion region 13A is aligned with the side 12Ab of the channel region 12A on the drain region 11A side in the plan view. The side 13Ac of the diffusion region 13A is aligned with the side 12Ac of the channel region 12A in the plan view. The side 13Ad of the diffusion region 13A is aligned with the side 12Ad of the channel region 12A in the plan view.

That is, in this embodiment, the diffusion region 13A is formed in a region from the side edge of the second bottom gate region 72A on the source region 10A side to a side edge of the channel region 12A on the drain region 11A side in the direction perpendicular to the top gate region 8A.

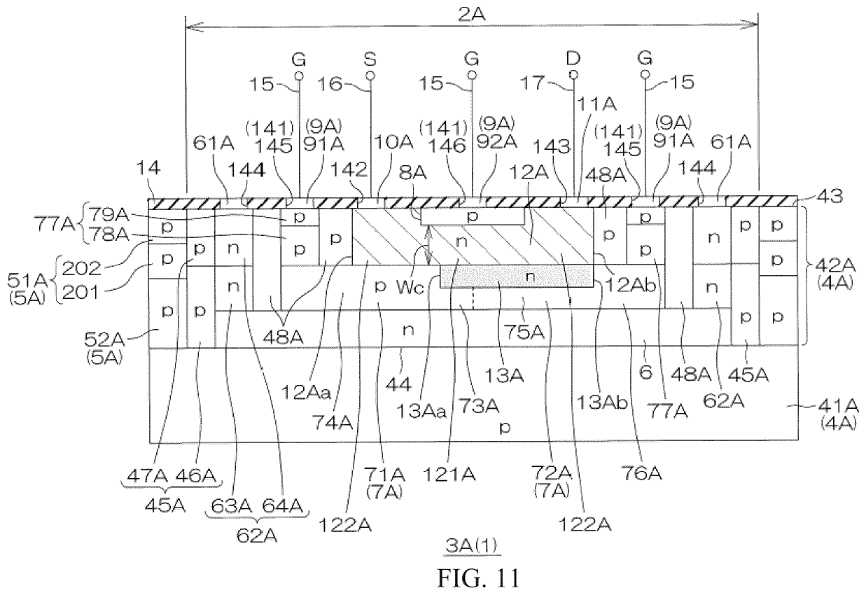

In addition, as shown in FIG. 11, in the plan view, the side 13Aa of the diffusion region 13A on the source region 10A side may be disposed between the side edge of the second bottom gate region 72A on the source region 10A side and a side edge of the source region 10A on the drain region 11A side.

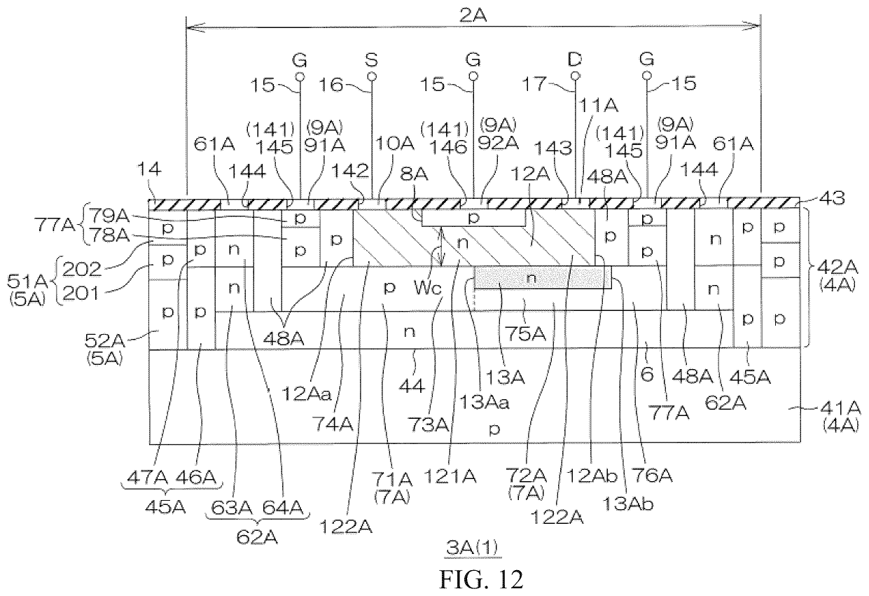

Moreover, as shown in FIG. 12, in the plan view, the side 13Ab of the diffusion region 13A on the drain region 11A side may be disposed between the side edge of the second bottom gate region 72A on the drain region 11A side and the gate middle region 77A (second linear portions 912A) on the drain region 11A side.

In this embodiment, the diffusion region 13A is formed in a region from the side 12Ac to the side 12Ad of the channel region 12A along the direction in which the top gate region 8A extends. In other words, in this embodiment, a length of the diffusion region 13A along the direction in which the top gate region 8A extends is equal to a length of the channel region 12A in such direction.

In the plan view, the sides 13Ac and 13Ad of the diffusion region 13A may extend further to an outside of the channel region 12A than the corresponding sides 12Ac and 12Ad of the channel region 12, respectively. In other words, the length of the diffusion region 13A along the direction in which the top gate region 8A extends may be greater than the length of the channel region 12A in such direction.

In the plan view, the diffusion region 13A does not exist in a region opposite to the drain region 11A side with respect to the side edge of the source region 10A on the drain region 11A side, while it preferably exists in a region including a region directly below the drain region 11A.

In the plan view, the diffusion region 13A does not exist in a region opposite to the drain region 11A side with respect to the side edge of the source region 10A on the drain region 11A side, while it preferably exists in a region including a region between a side edge of the top gate region 8A on the drain region 11A side and the side edge of the channel region 12A on the drain region 11A side.

In the plan view, the diffusion region 13A does not exist in a region opposite to the drain region 11A side with respect to the side edge of the source region 10A on the drain region 11A side, while it preferably exists in a region including a region between a center position between the source region 10A and the drain region 11A in the top gate region 8A and the side edge on the drain region 11A side in the channel region 12A.

In the n-channel JFET 3A, when a voltage is applied with the drain wiring 17 as a high potential side and the source wiring 16 as a low potential side, conduction occurs between the source region 10A and the drain region 11A via the channel region 12A. At this time, if no control voltage (gate voltage) is applied to the gate wiring 15, or if a control voltage (gate voltage) that is negative relative to the source potential to an extent such that the channel region is not blocked by the depletion layer is applied, a pn junction between the n-type channel region 12A and the p-type bottom gate region 7A, and a pn junction between the n-type channel region 12A and the p-type top gate region 8A will not extend out a sufficiently wide depletion layer.

That is, a current flowing through the channel region 12A in the direction along the element main surface 43 is not blocked by the depletion layer, and the n-channel JFET 3A is in an on state (normally on). On the other hand, if a gate voltage that is negative relative to the source potential that is higher than that at which the depletion layer can fully spread within the channel region 12A is applied to the gate wiring 15, it becomes difficult for electrons to move within the channel region 12A. As a result, the depletion layer blocks the movement of electrons in the channel region 12A.

In such the n-channel JFET 3A, the channel region 12A on the drain region 11A side is in a pinched-off state, and as the drain-source voltage Vds increases, an electric field strength near the drain region 11A increases. In this case, there is a possibility that an impact ionization phenomenon (impact ionization) occurs due to electrons moving from the source region 10A side to the drain region 11A side, and electron-hole pairs are generated. Since the charges (holes) generated at this time flow to the gate regions 7A and 8A, there is a possibility that the gate current becomes large.

In the n-channel JFET 3A according to this embodiment, the diffusion region 13A is formed in the surface layer portion of the bottom gate region 7A in a region of the source region 10A and the drain region 11A that is biased toward the drain region 11A side. Therefore, the electric field strength can be suppressed while the cut-off voltage remains low, so that the occurrence of impact ionization phenomenon can be suppressed. As a result, the gate current can be reduced.

[Method for manufacturing the n-channel JFET 3A]

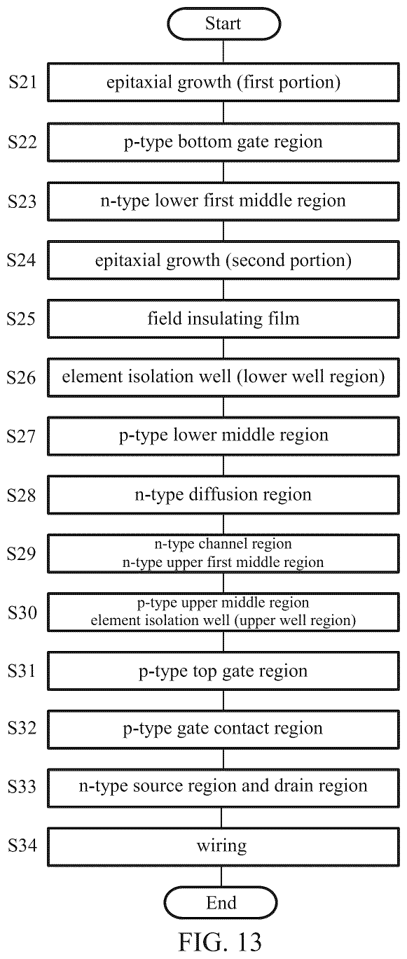

FIG. 13 is a flowchart showing part of a manufacturing process of the n-channel JFET 3A. Next, an example of the manufacturing process of the n-channel JFET 3A will be described with reference to FIG. 13.

To fabricate the n-channel JFET 3A, first, a p-type base substrate 41 is prepared. Next, n-type impurities and p-type impurities are selectively implanted into a surface of the base substrate 41. Next, silicon of the base substrate 41 is epitaxially grown while adding p-type impurities (step S21). Thus, a semiconductor substrate 4A including the p-type base substrate 41 and a first portion of an epitaxial layer 42A is formed. The first portion of the epitaxial layer 42A includes a region where a bottom gate region 7A is to be formed.

During the epitaxial growth of the base substrate 41A, the n-type impurities and the p-type impurities implanted into the base substrate 41 diffuse in a growth direction of the epitaxial layer 42A. Therefore, an n-type buried layer 6 and a p-type low isolation region 52 are formed at a boundary between the base substrate 41 and the epitaxial layer 42A.

Next, an ion implantation mask having an opening selectively disposed in a region where the bottom gate region 7A is to be formed is formed on the epitaxial layer 42 (the first portion). Then, p-type impurities are implanted into the epitaxial layer 42 through such ion implantation mask (step S22). Therefore, the p-type bottom gate region 7A is formed.

Next, an ion implantation mask having an opening selectively disposed in a region where a first middle region 62A is to be formed is formed on the epitaxial layer 42 (the first portion). Then, n-type impurities are implanted into the epitaxial layer 42 through such ion implantation mask (step S23). Therefore, an n-type lower first middle region 63A is formed.

Next, p-type impurities are selectively implanted into a surface of the epitaxial layer 42A (first portion) to form a portion of a well region 51A. Then, the silicon of the base substrate 41 is further epitaxially grown while adding p-type impurities (step S24). Therefore, a second portion of the epitaxial layer 42A is formed. As a result, the epitaxial layer 42A having an element main surface 43 and a bonding surface 44 is obtained.

Next, a field insulating film 14 is formed on the element main surface 43 of the epitaxial layer 42A (step S25).

Next, an ion implantation mask having an opening selectively disposed in a region where a p-type well region 51A is to be formed is formed on the field insulating film 14. Then, p-type impurities are implanted into the epitaxial layer 42A through such ion implantation mask (step S26). Therefore, a lower well region 201 of the p-type well region 51A is formed.

Next, an ion implantation mask having an opening selectively disposed in a region where a gate middle region 77A is to be formed is formed on the field insulating film 14. Then, p-type impurities are implanted into the epitaxial layer 42A through such ion implantation mask (step S27). Therefore, a lower middle region 78A of the gate middle region 77A is formed.

In addition, in a step (step S30) of forming an upper middle region 79A, which will be described later, the lower middle region 78A and the upper middle region 79A may be formed. In this case, the step S27 is omitted.

Next, an ion implantation mask having an opening selectively disposed in a region where a diffusion region 13A is to be formed is formed on the field insulating film 14. Then, n-type impurities are implanted into the epitaxial layer 42A through such ion implantation mask (step S28). Therefore, the n-type diffusion region 13A is formed.

Next, an ion implantation mask having openings selectively disposed in regions where a channel region 12A and a first middle region 62A are to be formed is formed on the field insulating film 14. Then, n-type impurities are implanted into the epitaxial layer 42A through such ion implantation mask (step S29. Therefore, the n-type channel region 12A and an upper first middle region 64A of the first middle region 62A are formed.

Next, an ion implantation mask having openings selectively disposed in regions where the gate middle region 77A and an element isolation portion 5A are to be formed is formed on the field insulating film 14. Then, p-type impurities are implanted into the epitaxial layer 42A through such ion implantation mask (step S30). Therefore, an upper middle region 79A of the gate middle region 77A is formed, and an upper well region 202 of the well region 51A is also formed. Therefore, the p-type gate middle region 77A is formed. Moreover, as a result, the element isolation portion 5 (an element isolation well) having a two-layer structure of the p-type well region 51A and the p-type low isolation region 52 is formed.

Next, an ion implantation mask having an opening selectively disposed in a region where a top gate region 8A is to be formed is formed on the field insulating film 14. Then, p-type impurities are implanted into the epitaxial layer 42A through such ion implantation mask (step S31). Therefore, the p-type top gate region 8A is formed.

Next, anion implantation mask having an opening selectively disposed in a region where a gate contact region 9A is to be formed is formed on the field insulating film 14. Then, p-type impurities are implanted into the epitaxial layer 42A through such ion implantation mask (step S32). Therefore, the p-type gate contact region 9A is formed.

Next, an ion implantation mask having openings selectively disposed in regions where a source region 10A and a drain region 11A are to be formed is formed on the field insulating film 14. Then, n-type impurities are implanted into the epitaxial layer 42A through such ion implantation mask (step S33). Therefore, the n-type source region 10A and the n-type drain region 11A are formed.

Next, the above-mentioned n-channel JFET 3A is obtained by performing a step of forming wirings 15 to 17 (step S34) and the like.

Note that the manufacturing process of the semiconductor device described using FIG. 13 as an example, and the n-channel JFET 3A may be manufactured by other manufacturing processes. For example, in the embodiments described above, the epitaxial layer 42A is formed in two stages, but the epitaxial layer 42A does not need to be formed in two stages. That is, in step S21, the epitaxial layer 42A having the element main surface 43 and the bonding surface 44 may be formed on the base substrate 41. In this case, the bottom gate region 7A, an outer epitaxial region 45A and an inner epitaxial region 48A may have the same p-type impurity concentration.

Moreover, in the embodiments described above, the p-type bottom gate region 7A is formed by implanting p-type impurities into the epitaxial layer 42A after step S21. However, after the field insulating film 14 is formed in step S25 and until the element isolation portion 5A is formed in step S26, a highly accelerated ion implantation is performed, so that the p-type bottom gate region 7A may be formed.

Moreover, in the embodiments described above, the lower well region 201 and the upper well region 202 are formed by separate ion implantation processes, but they may be formed by one and the same ion implantation process.

Moreover, in the embodiments described above, the lower first middle region 63A and the upper first middle region 64A are formed by separate ion implantation processes, but they may be formed by one and the same ion implantation process.

As described above, the embodiments of the present disclosure are illustrative in all respects and should not be construed as limiting, and are intended to include changes in all respects.

The features described below can be extracted from descriptions of the specification and drawings.

### [Note 1-1]

1. A semiconductor device (3, 3A), comprising:
   a semiconductor layer (42, 42A) of a first conductivity type, having a first surface (43);
   a bottom gate region (7, 7A) of the first conductivity type, formed in the semiconductor layer;
   a top gate region (8, 8A) of the first conductivity type, formed in a surface layer portion of the first surface of the semiconductor layer, wherein the top gate region faces the bottom gate region along a thickness direction of the semiconductor layer;
   a source region (10, 10A) of a second conductivity type, formed in the surface layer portion of the first surface of the semiconductor layer and separated from the top gate region in a direction along the first surface;
   a drain region (11, 11A) of the second conductivity type, formed in the surface layer portion of the first surface of the semiconductor layer and separated from the top gate region at an opposite side of the source region in the direction along the first surface; and
   a channel region (12, 12A) of the second conductivity type, formed between at least the source region and the drain region in the direction along the first surface, and between the bottom gate region and the top gate region along the thickness direction of the semiconductor layer, wherein
   in a surface layer portion of the bottom gate region, a diffusion region (13, 13A) of the second conductivity type is formed in a region of the source region and the drain region and biased toward a drain region side.

### [Note 1-2]

The semiconductor device of [Note 1-1], wherein in a plan view, the diffusion region (13, 13A) does not exist in a region opposite to the drain region side with respect to a side edge of the source region (10, 10A) on the drain region (11, 11A) side, while the diffusion region exists in a region including a region directly below the drain region.

### [Note 1-3]

The semiconductor device of [Note 1-1], wherein in a plan view, the diffusion region (13, 13A) does not exist in a region opposite to the drain region side with respect to a side edge of the source region (10, 10A) on the drain region (11, 11A) side, while the diffusion region exists in a region including a region between a side edge of the top gate region on the drain region side and a side edge of the channel region on the drain region side.

### [Note 1-4]

The semiconductor device of Claim [Note 1-1], wherein in a plan view, the diffusion region (13, 13A) does not exist in a region opposite to the drain region side with respect to a side edge of the source region (10, 10A) on the drain region (11, 11A) side, while the diffusion region exists in a region including a region between a center position between the source region and the drain region in the top gate region (8, 8A) and a side edge on the drain side of the channel region (12, 12A).

### [Note 1-5]

The semiconductor device of any one of [Note 1-1] to [Note 1-4], wherein
the first conductivity type is n type,
the second conductivity type is p type,
an impurity concentration of the second conductivity type of the channel region (12) is between about 5×10¹⁴ cm⁻³ and about 5×10¹⁸ cm⁻³, and
an impurity concentration of the second conductivity type of the diffusion region (13) is between about 5×10¹⁴ cm⁻³ and about 5×10¹⁸ cm⁻³.

### [Note 1-6]

The semiconductor device of [Note 1-5], wherein
an impurity concentration of the first conductivity type of the bottom gate region (7) is between about 5×10¹⁴ cm⁻³ and about 5×10¹⁸ cm⁻³, and
an impurity concentration of the first conductivity type of the top gate region (8) is between about 5×10¹⁴ cm⁻³ and about 5×10¹⁸ cm⁻³.

### [Note 1-7]

The semiconductor device of any one of [Note 1-1] to [Note 1-4], wherein
the first conductivity type is p type,
the second conductivity type is n type,
an impurity concentration of the second conductivity type of the channel region (12A) is between about 5×10¹⁴ cm⁻³ and about 5×10¹⁸ cm⁻³, and
an impurity concentration of the second conductivity type of the diffusion region (13A) is between about 5×10¹⁴ cm⁻³ and about 5×10¹⁸ cm⁻³.

### [Note 1-8]

The semiconductor device of [Note 1-7], wherein
an impurity concentration of the first conductivity type of the bottom gate region (7A) is between about 5×10¹⁴ cm⁻³ and about 5×10¹⁸ cm⁻³, and
an impurity concentration of the second conductivity type of the top gate region (8A) is between about 5×10¹⁴ cm⁻³ and about 5×10¹⁸ cm⁻³.

### [Note 1-9]

The semiconductor device of any one of [Note 1-1] to [Note 1-8], including:
an insulating layer formed on the first surface (43) of the semiconductor layer (42, 42A) and having an opening (142, 143) exposing the source region (10, 10A) and the drain region (11, 11A).

### [Note 1-10]

The semiconductor device of any one of [Note 1-1] to [Note 1-9], including:
a gate contact region (9, 9A) formed in the surface layer portion of the first surface (43) of the semiconductor layer (42, 42A) and electrically connected in common with the bottom gate region (7, 7A) and the top gate region (8, 8A), wherein
the bottom gate region is formed in an island shape in the plan view,
in the plan view, the gate contact region integrally includes:
   a first gate contact portion (91, 91A), formed in an annular shape along a peripheral edge portion of the bottom gate region, and electrically connected to the bottom gate region; and
   a second gate contact portion (92, 92A), formed across a plurality of locations of the first gate contact portion to divide the bottom gate region, and electrically connected to the top gate region.

### [Note 11]

The semiconductor device of [Note 1-10], wherein
in plan view, the bottom gate region (7, 7A) includes the first bottom gate region (71, 71A) and the second bottom gate region (72, 72A) separated by the second gate contact portion (92, 92A),
the source region (10, 10A) is formed on the first bottom gate region, and
the drain region (11, 11A) is formed on the second bottom gate region.

### [Note 1-12]

The semiconductor device of [Note 1-10], wherein
the first gate contact portion (91, 91A) is formed into a square ring in the plan view including a pair of first linear portions (911, 911A) facing each other and a pair of second linear portions (912, 912A) facing each other, and
the second gate contact portion (92, 92A) is formed in a straight line that connects the pair of first linear portions.

### [Note 1-13]

The semiconductor device of [Note 1-10], including: a gate middle region (77, 77A),
formed between the peripheral edge portion of the bottom gate region (7, 7A) and the first gate contact portion (911, 911A), and
having an impurity concentration of the first conductivity type lower than the impurity concentration of the first conductivity type of the bottom gate region and the impurity concentration of the first conductivity type of the gate contact region.

1. A semiconductor device, comprising:
a semiconductor layer of a first conductivity type, having a first surface;
a bottom gate region of the first conductivity type, formed in the semiconductor layer;
a top gate region of the first conductivity type, formed in a surface layer portion of the first surface of the semiconductor layer, wherein the top gate region faces the bottom gate region along a thickness direction of the semiconductor layer;
a source region of a second conductivity type, formed in the surface layer portion of the first surface of the semiconductor layer and separated from the top gate region in a direction along the first surface;
a drain region of the second conductivity type, formed in the surface layer portion of the first surface of the semiconductor layer and separated from the top gate region at an opposite side of the source region in the direction along the first surface; and
a channel region of the second conductivity type, formed between at least the source region and the drain region in the direction along the first surface, and between the bottom gate region and the top gate region along the thickness direction of the semiconductor layer, wherein
in a surface layer portion of the bottom gate region, a diffusion region of the second conductivity type is formed in a region of the source region and the drain region and biased toward a drain region side.

2. The semiconductor device of claim 1, wherein in a plan view, the diffusion region does not exist in a region opposite to the drain region side with respect to a side edge of the source region on the drain region side, while the diffusion region exists in a region including a region directly below the drain region.

3. The semiconductor device of claim 1, wherein in a plan view, the diffusion region does not exist in a region opposite to the drain region side with respect to a side edge of the source region on the drain region side, while the diffusion region exists in a region including a region between a side edge of the top gate region on the drain region side and a side edge of the channel region on the drain region side.

4. The semiconductor device of claim 1, wherein in a plan view, the diffusion region does not exist in a region opposite to the drain region side with respect to a side edge of the source region on the drain region side, while the diffusion region exists in a region including a region between a center position between the source region and the drain region in the top gate region and a side edge on the drain side of the channel region.

5. The semiconductor device of claim 1, wherein
the first conductivity type is n type,
the second conductivity type is p type,
an impurity concentration of the second conductivity type of the channel region is between about 5×10¹⁴ cm⁻³ and about 5×10¹⁸ cm⁻³, and
an impurity concentration of the second conductivity type of the diffusion region is between about 5×10¹⁴ cm⁻³ and about 5×10¹⁸ cm⁻³.

6. The semiconductor device of claim 2, wherein
the first conductivity type is n type,
the second conductivity type is p type,
an impurity concentration of the second conductivity type of the channel region is between about 5×10¹⁴ cm⁻³ and about 5×10¹⁸ cm⁻³, and
an impurity concentration of the second conductivity type of the diffusion region is between about 5×10¹⁴ cm⁻³ and about 5×10¹⁸ cm⁻³.

7. The semiconductor device of claim 3, wherein
the first conductivity type is n type,
the second conductivity type is p type,
an impurity concentration of the second conductivity type of the channel region is between about 5×10¹⁴ cm⁻³ and about 5×10¹⁸ cm⁻³, and
an impurity concentration of the second conductivity type of the diffusion region is between about 5×10¹⁴ cm⁻³ and about 5×10¹⁸ cm⁻³.

8. The semiconductor device of claim 4, wherein
the first conductivity type is n type,
the second conductivity type is p type,
an impurity concentration of the second conductivity type of the channel region is between about 5×10¹⁴ cm⁻³ and about 5×10¹⁸ cm⁻³, and
an impurity concentration of the second conductivity type of the diffusion region is between about 5×10¹⁴ cm⁻³ and about 5×10¹⁸ cm⁻³.

9. The semiconductor device of claim 5, wherein
an impurity concentration of the first conductivity type of the bottom gate region is between about 5×10¹⁴ cm⁻³ and about 5×10¹⁸ cm⁻³, and
an impurity concentration of the first conductivity type of the top gate region is between about 5×10¹⁴ cm⁻³ and about 5×10¹⁸ cm⁻³.

10. The semiconductor device of claim 1, wherein
the first conductivity type is p type,
the second conductivity type is n type,
an impurity concentration of the second conductivity type of the channel region is between about 5×10¹⁴ cm⁻³ and about 5×10¹⁸ cm⁻³, and
an impurity concentration of the second conductivity type of the diffusion region is between about 5×10¹⁴ cm⁻³ and about 5×10¹⁸ cm⁻³.

11. The semiconductor device of claim 2, wherein
the first conductivity type is p type,
the second conductivity type is n type,
an impurity concentration of the second conductivity type of the channel region is between about 5×10¹⁴ cm⁻³ and about 5×10¹⁸ cm⁻³, and
an impurity concentration of the second conductivity type of the diffusion region is between about 5×10¹⁴ cm⁻³ and about 5×10¹⁸ cm⁻³.

12. The semiconductor device of claim 3, wherein
the first conductivity type is p type,
the second conductivity type is n type,
an impurity concentration of the second conductivity type of the channel region is between about 5×10¹⁴ cm⁻³ and about 5×10¹⁸ cm⁻³, and
an impurity concentration of the second conductivity type of the diffusion region is between about 5×10¹⁴ cm⁻³ and about 5×10¹⁸ cm⁻³.

13. The semiconductor device of claim 10, wherein
an impurity concentration of the first conductivity type of the bottom gate region is between about 5×10¹⁴ cm⁻³ and about 5×10¹⁸ cm⁻³, and
an impurity concentration of the second conductivity type of the top gate region is between about 5×10¹⁴ cm⁻³ and about 5×10¹⁸ cm⁻³.

14. The semiconductor device of claim 1, including:
an insulating layer formed on the first surface of the semiconductor layer and having an opening exposing the source region and the drain region.

15. The semiconductor device of claim 2, including:
an insulating layer formed on the first surface of the semiconductor layer and having an opening exposing the source region and the drain region.

16. The semiconductor device of claim 1, including:
a gate contact region formed in the surface layer portion of the first surface of the semiconductor layer and electrically connected in common with the bottom gate region and the top gate region, wherein
the bottom gate region is formed in an island shape in a plan view,
in the plan view, the gate contact region integrally includes:
a first gate contact portion, formed in an annular shape along a peripheral edge portion of the bottom gate region, and electrically connected to the bottom gate region; and
a second gate contact portion, formed across a plurality of locations of the first gate contact portion to divide the bottom gate region, and electrically connected to the top gate region.

17. The semiconductor device of claim 2, including:
a gate contact region formed in the surface layer portion of the first surface of the semiconductor layer and electrically connected in common with the bottom gate region and the top gate region, wherein
the bottom gate region is formed in an island shape in the plan view,
in the plan view, the gate contact region integrally includes:
a first gate contact portion, formed in an annular shape along a peripheral edge portion of the bottom gate region, and electrically connected to the bottom gate region; and
a second gate contact portion, formed across a plurality of locations of the first gate contact portion to divide the bottom gate region, and electrically connected to the top gate region.

18. The semiconductor device of claim 16, wherein
in plan view, the bottom gate region includes the first bottom gate region and the second bottom gate region separated by the second gate contact portion,
the source region is formed on the first bottom gate region, and
the drain region is formed on the second bottom gate region.

19. The semiconductor device of claim 16, wherein
the first gate contact portion is formed into a square ring in the plan view including a pair of first linear portions facing each other and a pair of second linear portions facing each other, and
the second gate contact portion is formed in a straight line that connects the pair of first linear portions.

20. The semiconductor device of claim 16, including: a gate middle region,
formed between the peripheral edge portion of the bottom gate region and the first gate contact portion, and
having an impurity concentration of the first conductivity type lower than the impurity concentration of the first conductivity type of the bottom gate region and the impurity concentration of the first conductivity type of the gate contact region.
